(19) United States
(12) Patent Application Publication
(10) Pub. No.: US 2019/0221524 A1
(43) Pub. Date: Jul. 18, 2019

(54) THERMAL MANAGEMENT AND/OR EMI MITIGATION MATERIALS HAVING INCREASED CONTRAST AND PRESENCE DETECTION

(71) Applicant: Laird Technologies, Inc., Chesterfield, MO (US)

(72) Inventors: Karen J. Bruzda, Cleveland, OH (US); Jiannong Xu, Mayfield Village, OH (US)

(21) Appl. No.: 15/937,382

(22) Filed: Mar. 27, 2018

Related U.S. Application Data
(60) Provisional application No. 62/618,838, filed on Jan. 18, 2018.
(60) Provisional application No. 62/622,616, filed on Jan. 26, 2018.

(51) Int. Cl. H01L 23/552; H05K 9/00; H01L 23/367; H01L 23/427

(52) U.S. Cl. CPC H01L 23/552; H01L 23/427; H01L 23/367; H05K 9/0081

(57) ABSTRACT

Disclosed are exemplary embodiments of thermal management and/or EMI (electromagnetic interference) mitigation materials with one or more additives. The additives may include one or more phosphors; and/or one or more ultraviolet reactive additives; and/or one or more taggants; and/or one or more additives that are initially invisible to a naked human eye but increase in visibility to the naked human eye upon application of energy from an energy source corresponding to the one or more additives.

### CROSS-REFERENCE TO RELATED APPLICATIONS

This application claims priority to and the benefit of U.S. Provisional Patent Application No. 62/618,838 filed Jan. 18, 2018 and U.S. Provisional Patent Application No. 62/622,616 filed Jan. 26, 2018. The entire disclosures of the above applications are incorporated herein by reference.

### FIELD

The present disclosure relates to thermal management and/or EMI (electromagnetic interference) mitigation materials having increased contrast and presence detection.

### BACKGROUND

This section provides background information related to the present disclosure which is not necessarily prior art.

Electrical components, such as semiconductors, integrated circuit packages, transistors, etc., typically have pre-designed temperatures at which the electrical components optimally operate. Ideally, the pre-designed temperatures approximate the temperature of the surrounding air. But the operation of electrical components generates heat. If the heat is not removed, the electrical components may then operate at temperatures significantly higher than their normal or desirable operating temperature. Such excessive temperatures may adversely affect the operating characteristics of the electrical components and the operation of the associated device.

To avoid or at least reduce the adverse operating characteristics from the heat generation, the heat should be removed, for example, by conducting the heat from the operating electrical component to a heat sink. The heat sink may then be cooled by conventional convection and/or radiation techniques. During conduction, the heat may pass from the operating electrical component to the heat sink either by direct surface contact between the electrical component and heat sink and/or by contact of the electrical component and heat sink surfaces through an intermediate medium or thermal interface material (TIM). The thermal interface material may be used to fill the gap between thermal transfer surfaces, in order to increase thermal transfer efficiency as compared to having the gap filled with air, which is a relatively poor thermal conductor.

In addition, a common problem in the operation of electronic devices is the generation of electromagnetic radiation within the electronic circuitry of the equipment. Such radiation may result in electromagnetic interference (EMI) or radio frequency interference (RFI), which can interfere with the operation of other electronic devices within a certain proximity. Without adequate shielding, EMI/RFI interference may cause degradation or complete loss of important signals, thereby rendering the electronic equipment inefficient or inoperable.

A common solution to ameliorate the effects of EMI/RFI is through the use of shields capable of absorbing and/or reflecting and/or redirecting EMI energy. These shields are typically employed to localize EMI/RFI within its source, and to insulate other devices proximal to the EMI/RFI source.

The term “EMI” as used herein should be considered to generally include and refer to EMI emissions and RFI emissions, and the term “electromagnetic” should be considered to generally include and refer to electromagnetic and radio frequency from external sources and internal sources. Accordingly, the term shielding (as used herein) broadly includes and refers to mitigating (or limiting) EMI and/or RFI, such as by absorbing, reflecting, blocking, and/or redirecting the energy or some combination thereof so that it no longer interferes, for example, for government compliance and/or for internal functionality of the electronic component system.

### DRAWINGS

The drawings described herein are for illustrative purposes only of selected embodiments and not all possible implementations, and is not intended to limit the scope of the present disclosure.

FIG. 1 shows a thermal interface material including ultraviolet reactive additive according to an exemplary embodiment. The thermal interface material including ultraviolet reactive additive is positioned along an interior of an example board level shield.

FIG. 2 shows the thermal interface material including the ultraviolet reactive additive of FIG. 1 under a 365 nanometer 8 watt black light and showing fluorescence of the thermal interface material including the ultraviolet reactive additive.

FIG. 3 shows the exterior of the board level shield shown in FIG. 1.

FIG. 4 shows the exterior of the board level shield shown in FIG. 3 under a 365 nanometer 8 watt black light whereby a fluorescent portion of the thermal interface material including the ultraviolet reactive additive is visible through a hole in the board level shield.

FIG. 5 shows a thermal interface material including ultraviolet reactive additive according to an exemplary embodiment. The thermal interface material including ultraviolet reactive additive is positioned along an example metal shim.

FIG. 6 shows the thermal interface material including ultraviolet reactive additive of FIG. 5 now positioned between two metal shims.

FIG. 7 shows the thermal interface material including the ultraviolet reactive additive of FIG. 6 under a 365 nanometer 8 watt black light and showing fluorescence of the thermal interface material including the ultraviolet reactive additive between the two metal shims.

FIG. 8 shows a thermal interface material including the ultraviolet reactive additive according to an exemplary embodiment. The lower portion of the thermal interface material is not under a black light. But the upper portion of the thermal interface material is under a 365 nanometer 8 watt black light, and thereby shows fluorescence of the upper portion of thermal interface material including the ultraviolet reactive additive.

FIG. 9 is a line graph of attenuation in decibels per centimeter (dB/cm) versus frequency in gigahertz (GHz) for two TIM samples of a thermally-conductive microwave absorber. The first TIM sample included UV reactive pigment according to an exemplary embodiment. For comparison purposes, the second TIM sample did not include UV reactive pigment.

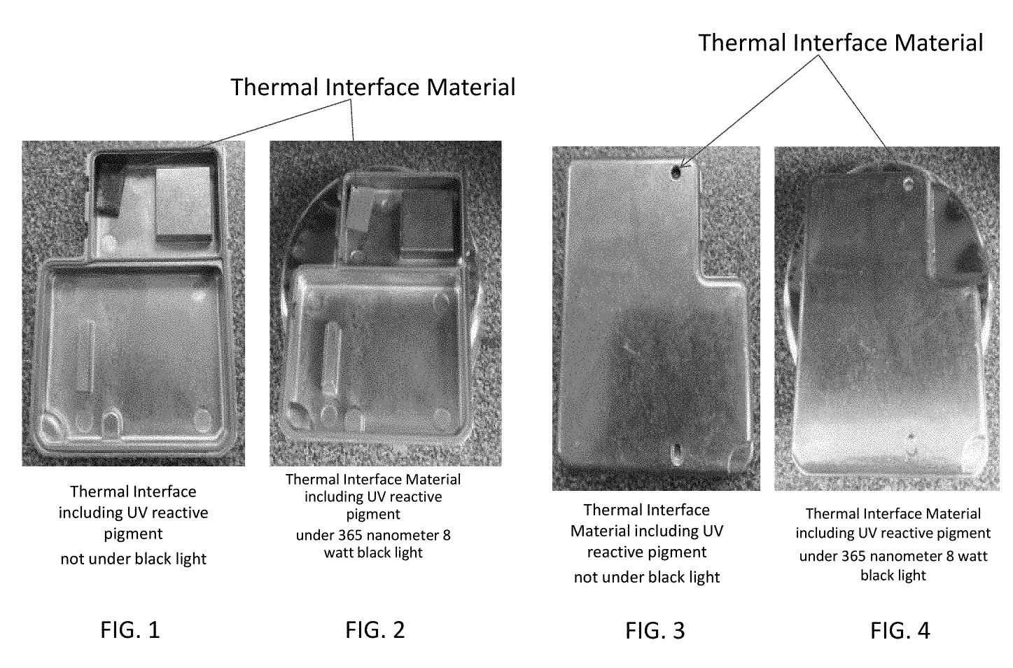

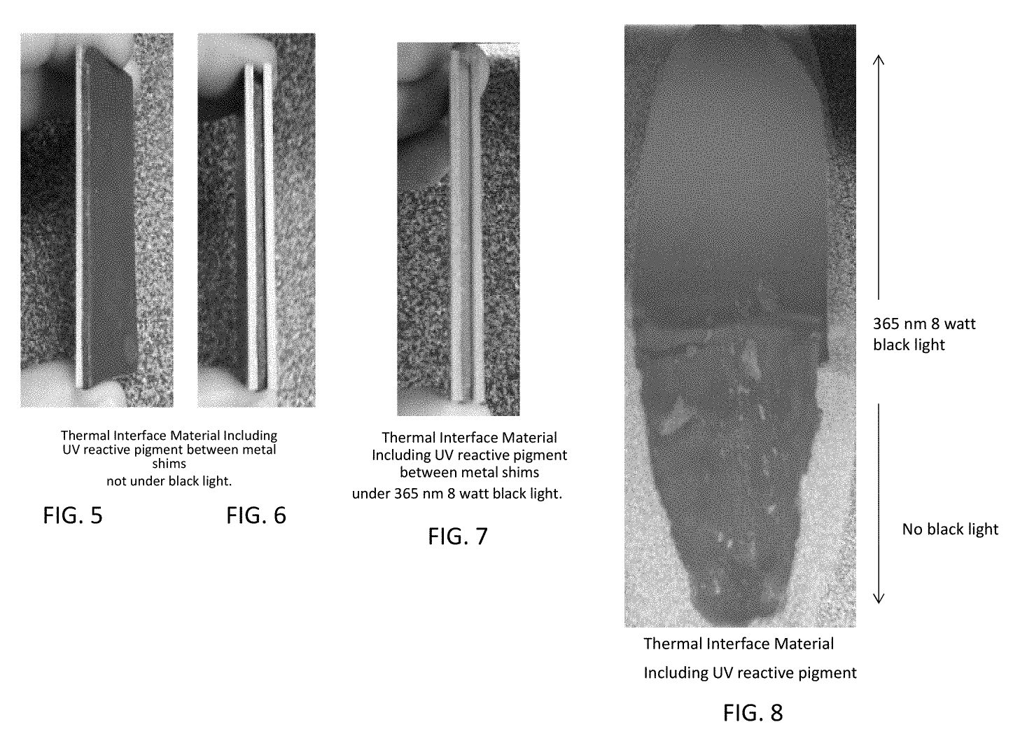

### DETAILED DESCRIPTION

Example embodiments will now be described more fully with reference to the accompanying drawings.

There is a need for increased contrast and presence detection of dark colored thermal management and/or EMI mitigation materials within applications. It can be beneficial to have materials that are differently colored so that the materials are easier to detect after the materials have been installed in an application due to the increased contrast from the surrounding system. This detection may be performed by an automated visual detection system or manually by the human eye. The detection may need to be performed through a small hole or from the side of a pad (e.g., a pad of thermal interface material, etc.).

With naturally dark colored materials, it is often impossible to change the color of the material significantly without significantly and negatively impacting the material's properties (e.g., decreasing thermal conductivity, reducing deflection, increasing hardness, etc.). For example, conventional surface coating technique may negatively impact material properties, e.g., reduce thermal conductivity of a thermal interface material, etc. And, surface coating techniques can be difficult to apply evenly.

Moreover, the surface coating may fail to cover “cut” edges of a pad of thermal interface material. In which case, a bulk material solution may be needed. Conventionally, large quantities of pigment have been added to change the color of a material, which pigment may significantly and negatively change the material's properties. By way of example, a thermal interface material (TIM) may conventionally be provided or made in only one color, which is set by either a pigment in the TIM formulation or by the natural color of the filler(s) (e.g., thermally-conductive filler, etc.) used in the TIM formulation. Similarly, a conventional EMI shielding material or absorber may also be provided or made in only one color, which is also set by either a pigment in the formulation or by the natural color of the filler(s) (e.g., electrically-conductive fillers, EMI absorbing particles, etc.) used in the formulation.

Accordingly, disclosed herein are exemplary embodiments that may allow for increased contrast and/or detection of thermal management and/or EMI mitigation materials by adding a relatively small quantity of one or more additives (e.g., about 1 to about 10 volume percent (vol %), about 30 to about 60 parts per million, etc.). The one or more additives may initially be invisible to the naked human eye but may increase in visibility upon application of energy from a particular energy source depending on the type of additive. By way of example, the additives may include phosphors (e.g., up-converting phosphors, etc.), ultraviolet (UV) reactive additives, fluorescent additives, taggants, molecular taggants, spectral taggants, security ink, glow-in-the-dark additives, additives that produce luminescence (e.g., photoluminescence, etc.), among other suitable additives that may initially be invisible to the naked human eye but which may increase in visibility upon application of a particular type of energy (e.g., ultraviolet light, black light, infrared light, laser, etc.), combinations thereof, etc.

The additives may be added to a bulk material (e.g., dispersed with high-speed mixing or moderate milling, etc.) without requiring a separate processing (e.g., surface coloring or coating, etc.) step. The additives may be incorporated into the bulk material such that the additives are well distributed throughout the resulting thermal management and/or EMI mitigation material. For example, the additives may be added to a bulk material mixture for a soft thermal gap filler, which may later be formed into a pad. The additives may cause the pad of the thermal interface material to have increased contrast from its surroundings upon application of a particular type of energy corresponding to the particular type of additives, such that the pad is detectable (e.g., from all six sides of the pad, etc.) and such that the material's properties (e.g., thermal conductivity, thermal resistance, modulus, hardness, and/or handleability, etc.) are not altered or not significantly altered.

In some exemplary embodiments, phosphors (e.g., up converting phosphors, etc.), ultraviolet reactive additives (e.g., ultraviolet reactive pigment, etc.), and/or taggants (e.g., molecular taggants, security ink, spectral taggants, microtaggants, etc.) may be added to a bulk material for a thermal management and/or EMI mitigation material without significantly degrading thermal management and/or EMI mitigation properties (e.g., thermal conductivity, thermal resistance, modulus, hardness, and/or handleability, etc.). Additionally, or alternatively, the phosphors, ultraviolet reactive additives, and/or taggants may be configured such that one or more thermal management and/or EMI mitigation properties are improved or enhanced.

For example, an exemplary embodiment includes adding an amount (e.g., about 1 vol % to 10 vol %, at least about 10 vol %, etc.) of phosphors (e.g., up converting phosphors, etc.) to a bulk material during a mixing step for a thermal management and/or EMI mitigation material. The addition of the phosphors allows the thermal management and/or EMI mitigation material to be detectable (e.g., presence confirmed, orientation ascertained, etc.) using infrared light. More specifically, the thermal management and/or EMI mitigation material can then be detected when the phosphors convert infrared light into visible colored light that is detectable. Accordingly, the thermal management and/or EMI mitigation material is thus detectable by virtue of the detectability of the visible colored light, which was converted from the invisible infrared light wavelengths by the phosphors.

Another exemplary embodiment includes adding an amount (e.g., about 2 vol %, etc.) of ultraviolet reactive additives (e.g., organic ultraviolet reactive pigments, quinazolinone, etc.) to a bulk material during a mixing step for a thermal management and/or EMI mitigation material. The ultraviolet reactive additives may be virtually invisible to the naked human eye until excited by ultraviolet light (e.g., ultraviolet light long wave 365 nanometers (nm) or short wave 254 nm, black light, etc.). The addition of the ultraviolet reactive additives allows the thermal management and/or EMI mitigation material to be detectable (e.g., presence confirmed, orientation ascertained, etc.) using an ultraviolet light source. The ultraviolet reactive additives will fluoresce under the ultraviolet light. The fluorescence will be readily differentiated from the surrounding area, thereby allowing the thermal management and/or EMI mitigation material to be readily detectable by or visible to the naked human eye or by an automated visual detection system.

A further exemplary embodiment includes adding an amount (e.g., about 30 to 60 parts per million, about 50 parts per million, etc.) of taggants (e.g., security ink, spectral taggants, microtaggants, molecular taggants, etc.) to a bulk material during a mixing step for a thermal management and/or EMI mitigation material. The addition of the taggants allows the thermal management and/or EMI mitigation material to be detectable (e.g., presence confirmed, orientation ascertained, etc.) with a handheld detector. By way of example, the handheld detector may comprise a taggant surface reader that is configured to detect taggants (e.g., security ink, spectral taggants, microtaggants, molecular taggants, up converting phosphors, etc.) and provide a user with a relatively immediate response (e.g., yes/no, etc.) during use. Or, for example, the handheld detector may comprise a handheld laser and ultraviolet detection device that is configured to produce laser and ultraviolet light for causing luminescence of taggants (e.g., microtaggants, up converting phosphors, etc.), which luminescence is detectable (e.g., visible to the naked human eye, etc.).

Accordingly, disclosed herein are thermal management and/or EMI mitigation materials that may be formed from bulk materials including one or more additives for increasing contrast and presence detection. The additives may or may not change a pre-existing or natural color (e.g., natural grey color, etc.) of the thermal management and/or EMI mitigation material. In other words, the color of the thermal management and/or EMI mitigation material with the additives may be the same or different than the color of the thermal management and/or EMI mitigation material without the additives. But as explained herein, the additives may initially be undetectable or invisible to the naked human eye, but the additives may increase in detectability (e.g., become visible to the naked human eye, etc.) upon application of a particular type of energy (e.g., ultraviolet light, black light, infrared light, laser, etc.).

The thermal management and/or EMI mitigation materials disclosed herein may comprise thermal interface materials (e.g., thermally-conductive pads or gap fillers, thermally-conductive dielectric materials, thermal phase change materials, thermal greases, thermal pastes, thermal putties, dispensable thermal interface materials, thermal pads, etc.), EMI shielding materials (e.g., EMI suppression materials, electrically-conductive thermal insulators, EMI absorbers etc.), microwave absorbers (e.g., microwave absorbing elastomers, microwave absorbing foams, EMI/RF/microwave absorbers, etc.), combinations thereof, etc. The thermal management and/or EMI mitigation materials disclosed herein may comprise combined thermal management and EMI mitigation materials, such as hybrid thermal/EMI absorbers, thermally-conductive microwave absorbers, hybrid absorber/thermal management materials usable for EMI mitigation, combined thermal interface and EMI shielding materials (e.g., thermally-conductive and electrically-conductive materials, thermally-conductive and EMI shielding/absorbing materials, etc.), etc.

In exemplary embodiments, automated visual detection systems may be used to confirm whether or not a thermal management and/or EMI mitigation materials, such as a thermal interface material, has been correctly installed or placed in an application. By way of background, a conventional automated vision system works most effectively when there is a significant difference in color and/or contrast between the thermal management and/or EMI mitigation material and the surrounding area, such as the substrate on which the thermal management and/or EMI mitigation material is placed. An automated vision system may not be able to detect a thermal management and/or EMI mitigation material and its relative positioning on a substrate or other surface if the exterior surface(s) of the thermal management and/or EMI mitigation material (e.g., an exposed, upwardly facing exterior surface, etc.) is the same color as the exterior surface(s) of the substrate (e.g., an exposed, upwardly facing portion of the substrate surface adjacent the thermal management and/or EMI mitigation material, etc.). If a thermal management and/or EMI mitigation material is missing or incorrectly placed, this could result in overheating of and/or damage to the electronic device.

In an exemplary embodiment, an automated visual detection system including an infrared light source may be used to confirm proper installation of a thermal management and/or EMI mitigation material that includes up converting phosphors as disclosed herein. In this example, the infrared light source may apply infrared light to at least a portion of the thermal management and/or EMI mitigation material that includes up converting phosphors. In response, the up converting phosphors may convert the infrared light into visible colored light that is detectable by the automated visual detection system.

In another exemplary embodiment, an automated visual detection system including an ultraviolet light source may be used to confirm proper installation of a thermal management and/or EMI mitigation material that includes ultraviolet reactive additives (e.g., ultraviolet reactive pigment, quinazolinone, etc.) as disclosed herein. In this example, the ultraviolet light source may apply ultraviolet light (e.g., ultraviolet long wave 365 nanometers or short wave 254 nanometers, black light, etc.) to at least a portion of the thermal management and/or EMI mitigation material that includes ultraviolet reactive additives. In response, detectable light is produced by fluorescence of the ultraviolet reactive additives in the thermal management and/or EMI mitigation material. The fluorescence differentiates the fluorescent thermal management and/or EMI mitigation material (or fluorescent portion thereof) from its surroundings thereby making the thermal management and/or EMI mitigation material easily detectable by the automated visual detection system.

In a further exemplary embodiment, an automated visual detection system includes a detector for detecting taggants (e.g., security ink, spectral taggants, microtaggants, molecular taggants, up converting phosphors, etc.) and that may be used to confirm proper installation of a thermal management and/or EMI mitigation material that includes taggants as disclosed herein. In this example, the detector may be applied to or along a surface of at least a portion of the thermal management and/or EMI mitigation material to detect the presence of taggants, and thereby confirm the presence of the thermal management and/or EMI mitigation material that includes the taggants.

In exemplary embodiments, a thermal management and/or electromagnetic interference (EMI) mitigation material may comprise one or more additives including one or more phosphors; and/or one or more ultraviolet reactive additives; and/or one or more taggants; and/or one or more additives that are initially invisible to a naked human eye but increase in visibility to the naked human eye upon application of energy from an energy source corresponding to the one or more additives.

The thermal management and/or electromagnetic interference (EMI) mitigation material may include an effective amount (e.g., about 1 vol % to 10 vol %, at least about 10 vol %, etc.) of the phosphors (e.g., up converting phosphors, etc.) such that when infrared light is applied to at least a portion the thermal management and/or electromagnetic interference (EMI) mitigation material including the phosphors, the infrared light is converted into visible colored light that may be visible to a naked human eye and/or distinguishable from a surrounding.

The thermal management and/or electromagnetic interference (EMI) mitigation material may include an effective amount (e.g., about 2 vol %, etc.) of the ultraviolet reactive additives (e.g., ultraviolet reactive pigment, quinazolinone, etc.) to cause fluorescence when ultraviolet light is applied to at least a portion of the thermal management and/or electromagnetic interference (EMI) mitigation material including the ultraviolet reactive additives. The fluorescence may be visible to a naked human eye and/or distinguishable from a surrounding.

The thermal management and/or electromagnetic interference (EMI) mitigation material may include an effective amount (e.g., about 50 parts per million, etc.) of the taggants (e.g., molecular taggants, etc.) that is detectable by a taggant detector.

The one or more additives may be incorporated (e.g., mixed, added, etc.) into a bulk material for the thermal management and/or EMI mitigation material without altering or without significantly altering thermal management and/or EMI mitigation properties (e.g., thermal conductivity, thermal resistance, modulus, hardness, and/or handleability, etc.) of the thermal management and/or EMI mitigation material.

The one or more additives may enable detectability of the thermal management and/or electromagnetic interference (EMI) mitigation material without applying a surface coating or colorant to exterior surfaces of the thermal management and/or electromagnetic interference (EMI) mitigation material.

The one or more additives may enable detectability of the thermal management and/or electromagnetic interference (EMI) mitigation material from all exterior sides of the thermal management and/or electromagnetic interference (EMI) mitigation material.

The thermal management and/or EMI mitigation material may comprise a pad of thermal interface material including a top, a bottom, and four sides. The one or more additives may enable detectability of the top, the bottom, and the four sides of the pad of thermal interface material by using one or more of infrared light when the one or more additives comprise one or more phosphors; ultraviolet light when the one or more additives comprise one or more ultraviolet reactive additives; and a taggant detector when the one or more additives comprise one or more taggants.

The thermal management and/or EMI mitigation material may be detectable by an automated visual detection system including an infrared light source when the one or more additives comprise one or more phosphors; an ultraviolet light source when the one or more additives comprise one or more ultraviolet reactive additives; and a taggant detector when the one or more additives comprise one or more taggants.

The one or more additives may comprise one or more ultraviolet reactive additives, which, in turn, may comprise quinazolinone. Generally, quinazolinone is a heterocyclic chemical compound and has two structural isomers, specifically 2-quinazolinone and 4-quinazolinone. In an exemplary embodiment, the ultraviolet reactive additives comprise a quinazolinone organic ultraviolet reactive pigment that is virtually or completely invisible to the naked human eye until excited by ultraviolet light long wave 365 nm or short wave 254 nm. In this example, the thermal management and/or EMI mitigation material included about 0.89 weight % (wt %) and about 2 vol % of the quinazolinone organic ultraviolet reactive pigment, which was mixed in a first addition step of the formulation with resins and coupling agent. By way of further example, the quinazolinone organic ultraviolet reactive pigment may have a green emission color, a peak emission of 507 nm, a specific gravity of 1.02, an average particle size of about 5 micrometers, a maximum processing temperature of 250 degrees Celsius, and a bulk density of 0.183 grams per milliliter. In alternative embodiments, a thermal management and/or EMI mitigation material may include more or less than 0.89 weight % (wt %) and 2 vol % of ultraviolet reactive additives and/or different ultraviolet reactive additives, e.g., an ultraviolet reactive additive having one or more different properties than those disclosed above.

The thermal management and/or EMI mitigation material may comprise a thermally-conductive microwave absorber including silicon carbide, carbonyl iron powder, and alumina; or a thermally-conductive microwave absorber including silicon carbide, carbonyl iron powder, alumina, manganese zinc ferrite, and magnetic flakes; or a surface wave absorber comprising a magnetically loaded silicone-based elastomeric sheet; or a tuned frequency absorber comprising a sheet including one or more magnetic fillers in a polymeric binder; or a thermal interface material comprising a thermally-conductive gap filler, a thermally-conductive silicone pad, and/or a thermally-conductive dielectric material; or an EMI shielding material comprising an EMI absorber, an EMI suppression material, and/or electrically-conductive thermal insulator; or a combined thermal interface and EMI shielding material comprising a thermally-conductive electrical conductor, a thermally-conductive EMI absorber, and/or a thermally conductive EMI suppression material.

The one or more additives may comprise the one or more ultraviolet reactive additives, which, in turn, may comprise quinazolinone. The one or more additives may comprise the one or more phosphors, which, turn, may comprise up converting phosphors. The one or more additives comprise the one or more taggants, which, turn, may comprise molecular taggants.

An automated visual detection system for detecting the thermal management and/or EMI mitigation material may comprise at least one or more of an infrared light source, an ultraviolet light source, and a taggant detector.

Also disclosed are exemplary embodiments of methods that may generally include adding one or more additives to a thermal management and/or EMI mitigation material. The one or more additives may include one or more phosphors; and/or one or more ultraviolet reactive additives; and/or one or more taggants; and/or one or more additives that are initially invisible to a naked human eye but increase in visibility to the naked human eye upon application of energy from an energy source corresponding to the one or more additives.

Adding one or more additives to a thermal management and/or EMI mitigation material may comprise adding an effective amount of the one or more phosphors such that when infrared light is applied to the thermal management and/or electromagnetic interference (EMI) mitigation material the infrared light is converted into visible colored light. The visible colored light may be visible to a naked human eye and/or distinguishable from a surrounding.

Adding one or more additives to a thermal management and/or EMI mitigation material may comprise adding an effective amount of the one or more ultraviolet reactive additives to cause fluorescence when ultraviolet light is applied to at least a portion of the thermal management and/or electromagnetic interference (EMI) mitigation material including the one or more ultraviolet reactive additives. The fluorescence is visible to a naked human eye and/or distinguishable from a surrounding.

Adding one or more additives to a thermal management and/or EMI mitigation material may comprise adding an effective amount of the one or more taggants that is detectable by a taggant detector.

Adding one or more additives to a thermal management and/or EMI mitigation material may comprise adding the one or more additives to a bulk material for the thermal management and/or EMI mitigation material.

Adding one or more additives to a thermal management and/or EMI mitigation material may enable detectability of the thermal management and/or electromagnetic interference (EMI) mitigation material without applying a surface coating or colorant to exterior surfaces of the thermal management and/or electromagnetic interference (EMI) mitigation material; and/or may enable detectability of the thermal management and/or electromagnetic interference (EMI) mitigation material from all exterior sides of the thermal management and/or electromagnetic interference (EMI) mitigation material.

The thermal management and/or EMI mitigation material may comprise a pad of thermal interface material including a top, a bottom, and four sides. The one or more additives may enable detectability of the top, the bottom, and the four sides of the pad of thermal interface material by using one or more of infrared light when the one or more additives comprise the one or more phosphors; ultraviolet light when the one or more additives comprise the one or more ultraviolet reactive additives; and a taggant detector when the one or more additives comprise the one or more taggants.

The thermal management and/or EMI mitigation material may comprise a thermally-conductive microwave absorber including silicon carbide, carbonyl iron powder, and alumina; or a thermally-conductive microwave absorber including silicon carbide, carbonyl iron powder, alumina, manganese zinc ferrite, and magnetic flakes; or a surface wave absorber comprising a magnetically loaded silicone-based elastomeric sheet; or a tuned frequency absorber comprising a sheet including one or more magnetic fillers in a polymeric binder; or a thermal interface material comprising a thermally-conductive gap filler, a thermally-conductive silicone pad, and/or a thermally-conductive dielectric material; or an EMI shielding material comprising an EMI absorber, an EMI suppression material, and/or electrically-conductive thermal insulator; or a combined thermal interface and EMI shielding material comprising a thermally-conductive electrical conductor, a thermally-conductive EMI absorber, and/or a thermally conductive EMI suppression material.

The one or more additives may comprise the one or more ultraviolet reactive additives, which, in turn, may comprise quinazolinone. The one or more additives may comprise the one or more phosphors, which, turn, may comprise up converting phosphors. The one or more additives comprise the one or more taggants, which, turn, may comprise molecular taggants.

Also disclosed are exemplary embodiments of methods of detecting a thermal management and/or EMI mitigation material including one or more additives. An exemplary method may generally include one or more of applying infrared light to at least a portion of the thermal management and/or EMI mitigation material including the one or more additives when the one or more additives comprise one or more phosphors; applying ultraviolet light to at least a portion of the thermal management and/or EMI mitigation material including the one or more additives when the one or more additives comprise one or more ultraviolet reactive additives; using a taggant detector along at least a portion of the thermal management and/or EMI mitigation material including the one or more additives when the one or more additives comprise one or more taggants; and/or applying energy from an energy source corresponding to the one or more additives to at least a portion of the thermal management and/or EMI mitigation material including the one or more additives to thereby increase visibility of the one or more additives that are initially invisible to a naked human eye.

The one or more additives may comprise one or more phosphors. The method may include applying infrared light to at least a portion of the thermal management and/or EMI mitigation material including the one or more phosphors such that the infrared light is converted into visible colored light. The visible colored light may be visible to a naked human eye and/or distinguishable from a surrounding.

The one or more additives may comprise one or more ultraviolet reactive additives. The method may include applying ultraviolet light to at least a portion the thermal management and/or EMI mitigation material including the one or more ultraviolet reactive additives to cause fluorescence. The fluorescence may be visible to a human eye and/or distinguishable from a surrounding.

The one or more additives may comprise one or more taggants. The method may include using a taggant detector to detect the one or more taggants in the thermal management and/or electromagnetic interference (EMI) mitigation material.

In exemplary methods, the thermal management and/or EMI mitigation material may comprise a pad of thermal interface material including a top, a bottom, and four sides. The one or more additives may enable detectability of the top, the bottom, and the four sides of the pad of thermal interface material. The method may include one or more of applying infrared light to any one or more of the top, the bottom, and the four sides of the pad of thermal interface material to detect the thermal management and/or EMI mitigation material when the one or more additives comprise the one or more phosphors; applying ultraviolet light to any one or more of the top, the bottom, and the four sides of the pad of thermal interface material to detect the thermal management and/or EMI mitigation material when the one or more additives comprise the one or more ultraviolet reactive additives; and using a taggant detector along any one or more of the top, the bottom, and the four sides of the pad of thermal interface material to detect the thermal management and/or EMI mitigation material when the one or more additives comprise the one or more taggants.

In exemplary methods, the thermal management and/or EMI mitigation material may comprise a thermally-conductive microwave absorber including silicon carbide, carbonyl iron powder, and alumina; or a thermally-conductive microwave absorber including silicon carbide, carbonyl iron powder, alumina, manganese zinc ferrite, and magnetic flakes; or a surface wave absorber comprising a magnetically loaded silicone-based elastomeric sheet; or a tuned frequency absorber comprising a sheet including one or more magnetic fillers in a polymeric binder; or a thermal interface material comprising a thermally-conductive gap filler, a thermally-conductive silicone pad, and/or a thermally-conductive dielectric material; or an EMI shielding material comprising an EMI absorber, an EMI suppression material, and/or electrically-conductive thermal insulator; or a combined thermal interface and EMI shielding material comprising a thermally-conductive electrical conductor, a thermally-conductive EMI absorber, and/or a thermally conductive EMI suppression material.

The one or more additives may comprise the one or more ultraviolet reactive additives, which, in turn, may comprise quinazolinone. The method may include applying ultraviolet light long wave 365 nanometers or short wave 254 nanometers to at least a portion of the thermal management and/or EMI mitigation material including the quinazolinone to cause fluorescence. The fluorescence may be visible to a human eye and/or distinguishable from a surrounding.

The one or more additives may comprise the one or more ultraviolet reactive additives, which, in turn, may comprise quinazolinone. The one or more additives may comprise the one or more phosphors, which, turn, may comprise up converting phosphors. The one or more additives comprise the one or more taggants, which, turn, may comprise molecular taggants.

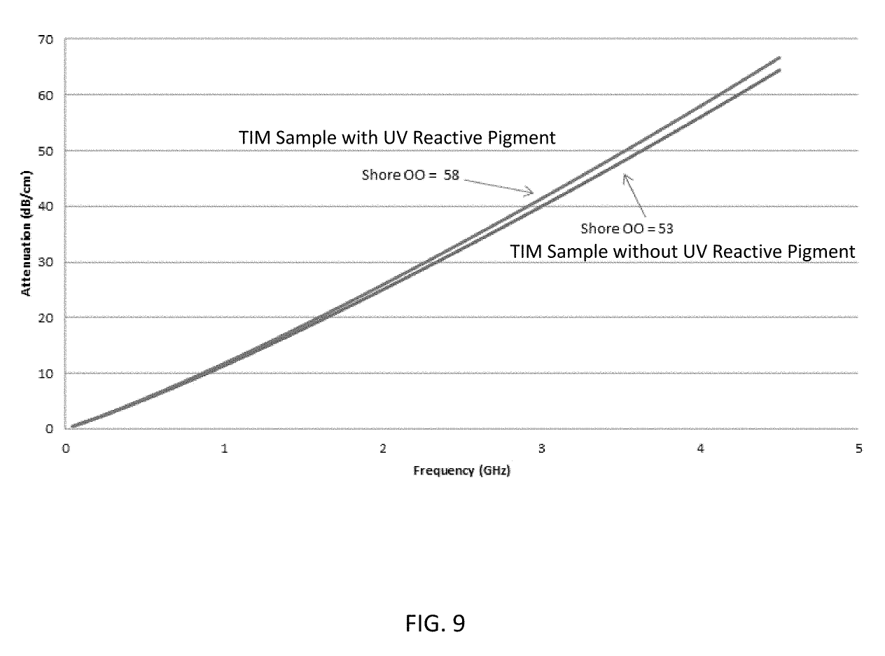

FIG. 9 is a line graph of attenuation in decibels per centimeter (dB/cm) versus frequency in gigahertz (GHz) for two TIM samples of a thermally-conductive microwave absorber. The first TIM sample was a thermally conductive microwave absorber including UV reactive pigment or indicator according to an exemplary embodiment. For comparison purposes, the second TIM sample was the same thermally conductive microwave absorber without any of the UV reactive pigment or indicator. The first TIM sample that included the UV reactive pigment had a hardness of Shore 00 of 58, whereas the second r TIM sample without the UV reactive pigment had a hardness of Shore 00 of 53. As shown by FIG. 9, the attenuation for the first TIM sample with the UV reactive pigment was similar to the attenuation for the second TIM sample without the UV reactive pigment. Accordingly, the addition of the UV reactive pigment did not appreciably or significantly negatively change the attenuation properties of the thermally conductive microwave absorber. The values for the hardness and attenuation disclosed herein and in FIG. 9 are examples only as other exemplary embodiments may be configured differently, e.g., harder, softer, different attenuation, etc.

The addition of the UV reactive pigment or indicator also did not significantly decrease (e.g., not more than about a 10% decrease, etc.) the effective thermal conductivity (thickness/thermal resistance) of the thermally conductive microwave absorber. The table below includes effective thermal conductivity for two TIM samples of a thermally-conductive microwave absorber. The first TIM sample was a thermally conductive microwave absorber including UV reactive pigment or indicator according to an exemplary embodiment. For comparison purposes, the second TIM sample was the same thermally conductive microwave absorber without any of the UV reactive pigment or indicator.

As shown by the table below, the first TIM sample that included the UV reactive pigment had a thermal resistance (Rth) of 1.722° Cin²/W at 20 psi, a final thickness of 1.461 millimeters (mm), and effective thermal conductivity (Tc) of 1.31 W/mK. The first TIM sample that included the UV reactive pigment also had a thermal resistance (Rth) of 1.608° Cin²/W at 50 psi, a final thickness of 1.363 mm, and effective thermal conductivity (Tc) of 1.31 W/mK. By comparison, the second TIM sample without the UV reactive pigment had a thermal resistance (Rth) of 1.125° Cin²/W at 20 psi, a final thickness of 1.055 millimeters (mm), and effective thermal conductivity (Tc) of 1.45 W/mK. The second TIM sample without the UV reactive pigment also had a thermal resistance (Rth) of 1° Cin²/W at 50 psi, a final thickness of 0.919 millimeters (mm), and effective thermal conductivity (Tc) of 1.42 W/mK. Accordingly, the addition of the UV reactive pigment did not significantly decrease the effective thermal conductivity (thickness/thermal resistance) of the thermally conductive microwave absorber, e.g., about 9% decrease, about 0.14 W/mK decrease at 20 psi, about 0.11 W/mK decrease at 50 psi, etc. The values for the thermal resistance, thickness, and effective thermal conductivity disclosed herein and in the table below are examples only as other exemplary embodiments may be configured differently, e.g., thicker, thinner, have a different thermal resistance, have a different effective thermal conductivity, etc.

| | Thermal | | Effective | | | Effective |
|---|---|---|---|---|---|---|
| | Resistance | Final | Thermal | Thermal | Final | Thermal |
| | Rth (° Cin²/W) | Thickness | Conductivity | Resistance Rth | Thickness | Conductivity |
| | at 20 psi | (mm) | Tc (W/mK) | (° Cin²/W) at 50 psi | (mm) | Tc (W/mK) |
| With UV | 1.722 | 1.461 | 1.31 | 1.608 | 1.363 | 1.31 |
| indicator | | | | | | |
| Without UV | 1.125 | 1.055 | 1.45 | 1 | 0.919 | 1.42 |
| indicator | | | | | | |

As used herein, thermal management and/or EMI mitigation materials include EMI mitigation materials that are operable for providing EMI mitigation but which are not good thermal conductors, such as electrically-conductive thermal insulators, EMI absorbing/suppressing thermal insulators, microwave absorbing/suppressing thermal insulators, etc. Additionally, thermal management and/or EMI mitigation materials include thermal interface materials that do not provide any EMI shielding, such as thermally-conductive dielectric pads or gap fillers, thermally-conductive electric insulators, thermally-conductive dielectric materials, etc. Further, the thermal management and/or EMI mitigation materials include hybrid or combined thermal management and EMI mitigation materials that are operable for both EMI mitigation and thermal management, such as hybrid thermal/EMI absorbers, thermally-conductive microwave absorbers, hybrid absorber/thermal management materials usable for EMI mitigation, combined thermal interface and EMI shielding materials (e.g., thermally-conductive and electrically-conductive materials, thermally-conductive and EMI shielding/absorbing/suppressing materials, etc.), etc.

A wide range of thermal management and/or EMI mitigation materials may have their bulk material formulations modified to include one or more additives in accordance with exemplary embodiments disclosed herein. Example thermal interface materials include thermal gap fillers, thermal phase change materials, thermally-conductive EMI absorbers or hybrid thermal/EMI absorbers, thermal greases, thermal pastes, thermal putties, dispensable thermal interface materials, thermal pads, etc. Example embodiments may include one or more thermal interface materials of Laird, such as any one or more of the Tflex™ series gap fillers (e.g., Tflex™ series thermal gap filler materials, Tflex™ 600 series thermal gap filler materials, Tflex™ HR600 series thermal gap filler materials, Tflex™ 700 series thermal gap filler materials, Tflex™ 800 series silicone free thermal gap filler materials, etc.), Tpcm™ series thermal phase change materials (e.g., Tpcm™ 580 series phase change materials, etc.), Tpli™ series gap fillers (e.g., Tpli™ series gap fillers, etc.), IceKap™ series thermal interface materials, CoolZorb™ series thermally conductive microwave absorber materials (e.g., CoolZorb™ 400 series thermally conductive microwave absorber materials, CoolZorb™ 500 series thermally conductive microwave absorber materials, CoolZorb™ 600 series thermally conductive microwave absorber materials, CoolZorb™ 700 series thermally conductive microwave absorber materials, etc.), Q-ZORB™ microwave absorbing elastomer (e.g., Q-ZORB™ HP (high permeability), Q-ZORB™ HF (high frequency), etc.), foam absorbers (e.g., RFLS™ single layer lossy foam absorber sheet, Lossy sheets, RFRET™ reticulated foam based absorber, etc.), etc.

By way of further example, a thermal management and/or EMI mitigation material may comprise an elastomer and/or ceramic particles, metal particles, ferrite EMI/RFI absorbing particles, metal or fiberglass meshes in a base of rubber, gel, or wax, etc. A thermal management and/or EMI mitigation material may include compliant or conformable silicone pads, non-silicone based materials (e.g., non-silicone based gap filler materials, thermoplastic and/or thermoset polymeric, elastomeric materials, etc.), silk screened materials, polyurethane foams or gels, thermally-conductive additives, etc. A thermal management and/or EMI mitigation material may be configured to have sufficient conformability, compliability, and/or softness (e.g., without having to undergo a phase change or reflow, etc.) to adjust for tolerance or gaps by deflecting at low temperatures (e.g., room temperature of 20° C. to 25° C., etc.) and/or to allow the material to closely conform (e.g., in a relatively close fitting and encapsulating manner, etc.) to a mating surface when placed in contact with the mating surface, including a non-flat, curved, or uneven mating surface. For example, the thermal management and/or EMI mitigation material may have very high compliancy such that the thermal management and/or EMI mitigation material will relatively closely conform to the size and outer shape of an electrical component when the thermal management and/or EMI mitigation material is along an inner surface of a cover of an EMI shield (e.g., a one-piece or two board level shield, etc.) and the thermal management and/or EMI mitigation material is compressed against the electrical component when the EMI shield is installed to a printed circuit board over the electrical component.

A thermal management and/or EMI mitigation material may comprise a soft thermal interface material formed from elastomer and at least one thermally-conductive metal, boron nitride, and/or ceramic filler, such that the soft thermal interface material is conformable even without undergoing a phase change or reflow. The thermal management and/or EMI mitigation material may be a non-metal, non-phase change material that does not include metal and that is conformable even without undergoing a phase change or reflow. A thermal management and/or EMI mitigation material may comprise a thermal interface phase change material. A thermal management and/or EMI mitigation material may comprise a ceramic filled silicone elastomer, boron nitride filled silicone elastomer, fiberglass reinforced gap filler, or a thermal phase change material that includes a generally non-reinforced film.

A thermal management and/or EMI mitigation material may be a non-phase change material and/or be configured to adjust for tolerance or gap by deflection. In some exemplary embodiments, the thermal management and/or EMI mitigation material may comprise a non-phase change gap filler or gap pad that is conformable without having to melt or undergo a phase change. The thermal management and/or EMI mitigation material may be able to adjust for tolerance or gaps by deflecting at low temperatures (e.g., room temperature of 20° C. to 25° C., etc.). The thermal management and/or EMI mitigation material may have a Young's modulus and Hardness Shore value considerably lower than copper or aluminum. The thermal management and/or EMI mitigation material may also have greater percent deflection versus pressure than copper or aluminum.

In some exemplary embodiments, the thermal management and/or EMI mitigation material comprises Tflex™ 300 ceramic filled silicone elastomer gap filler or Tflex™ 600 boron nitride filled silicone elastomer gap filler. Tflex™ 300 ceramic filled silicone elastomer gap filler and Tflex™ 600 boron nitride filled silicone elastomer gap filler have a Shore 00 hardness value (per the ASTM D2240 test method) of about 27 and 25, respectively. In some other exemplary embodiments, the thermal management and/or EMI mitigation material may comprise Tpli™ 200 boron nitride filled, silicone elastomer, fiberglass reinforced gap filler having a Shore 00 hardness of about 70 or 75. Accordingly, exemplary embodiments may include thermal management and/or EMI mitigation materials having a Shore 00 hardness less than 100. Tflex™ 300 series thermal gap filler materials generally include, e.g., ceramic filled silicone elastomer which will deflect to over 50% at pressures of 50 pounds per square inch and other properties shown below. Tflex™ 600 series thermal gap filler materials generally include boron nitride filled silicone elastomer, and have a hardness of 25 Shore 00 or 40 Shore 00 per ASTM D2240. Tpli™ 200 series gap fillers generally include reinforced boron nitride filled silicone elastomer and have a hardness of 75 Shore 00 or 70 Shore 00 per ASTM D2240. Tpcm™ 580 series phase change materials are generally non-reinforced films having a phase change softening temperature of about 122 degrees Fahrenheit (50 degrees Celsius). Other exemplary embodiments may include a thermal management and/or EMI mitigation material with a hardness of less than 25 Shore 00, greater than 75 Shore 00, between 25 and 75 Shore 00, 58 Shore 00, etc.

In some exemplary embodiments, the thermal management and/or EMI mitigation material may comprise a thermally-conductive microwave/RF/EMI absorber that includes silicon carbide. For example, the thermal management and/or EMI mitigation material may include silicon carbide, carbonyl iron powder, and alumina. In some exemplary embodiments, the thermal management and/or EMI mitigation material may further include manganese zinc (MnZn) ferrite and magnetic flakes. The resulting thermally-conductive EMI absorber may have a high thermal conductivity (e.g., at least 2 Watts per meter per Kelvin (W/m-K) or higher, etc.) and high EMI absorption or attenuation (e.g., at least 9 decibels per centimeter (dB/cm) at a frequency of at least 1 GHz, at least 17 dB/cm at a frequency of at least 15 GHz, etc.). In other exemplary embodiments, the thermal management and/or EMI mitigation material may comprise a thermally-conductive EMI absorber that includes one or more other ceramics, and/or other EMI absorbing materials.

Exemplary embodiments may include a thermal management and/or EMI mitigation material having a high thermal conductivity (e.g., 1 W/mK (watts per meter per Kelvin), 1.1 W/mK, 1.2 W/mK, 2.8 W/mK, 3 W/mK, 3.1 W/mK, 3.8 W/mK, 4 W/mK, 4.7 W/mK, 5 W/mK, 5.4 W/mK, 6W/mK, etc.) depending on the particular materials used to make the material and loading percentage of the thermally conductive filler, if any. These thermal conductivities are only examples as other embodiments may include a thermal management and/or EMI mitigation material with a thermal conductivity higher than 6 W/mK, less than 1 W/mK, or other values between 1 and 6 W/mk. Accordingly, aspects of the present disclosure should not be limited to use with any particular thermal management and/or EMI mitigation material as exemplary embodiments may include a wide range of thermal management and/or EMI mitigation materials.

In exemplary embodiments, a thermal interface material may be used to define or provide part of a thermally-conductive heat path from a heat source to a heat removal/dissipation structure or component. A thermal interface material disclosed herein may be used, for example, to help conduct thermal energy (e.g., heat, etc.) away from a heat source of an electronic device (e.g., one or more heat generating components, central processing unit (CPU), die, semiconductor device, etc.). A thermal interface material may be positioned generally between a heat source and a heat removal/dissipation structure or component (e.g., a heat spreader, a heat sink, a heat pipe, a device exterior case or housing, etc.) to establish a thermal joint, interface, pathway, or thermally-conductive heat path along which heat may be transferred (e.g., conducted) from the heat source to the heat removal/dissipation structure or component. During operation, the thermal interface material may then function to allow transfer (e.g., to conduct heat, etc.) of heat from the heat source along the thermally-conductive path to the heat removal/dissipation structure or component. In exemplary embodiments in which the thermal interface material is also an EMI absorber, the thermal interface/EMI absorbing material may also be operable for absorbing a portion of the EMI incident upon the thermal interface/EMI absorbing material.

Example embodiments of thermal management and/or EMI mitigation materials disclosed herein may be used with a wide range of heat sources, electronic devices, and/or heat removal/dissipation structures or components (e.g., a heat spreader, a heat sink, a heat pipe, a device exterior case or housing, etc.). For example, a heat source may comprise one or more heat generating components or devices (e.g., a CPU, die within underfill, semiconductor device, flip chip device, graphics processing unit (GPU), digital signal processor (DSP), multiprocessor system, integrated circuit, multi-core processor, etc.). Generally, a heat source may comprise any component or device that has a higher temperature than the thermal management and/or EMI mitigation material or otherwise provides or transfers heat to the thermal management and/or EMI mitigation material regardless of whether the heat is generated by the heat source or merely transferred through or via the heat source. Accordingly, aspects of the present disclosure should not be limited to use with any single type of heat source, electronic device, heat removal/dissipation structure, etc.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms, and that neither should be construed to limit the scope of the disclosure. In some example embodiments, well-known processes, well-known device structures, and well-known technologies are not described in detail. In addition, advantages and improvements that may be achieved with one or more exemplary embodiments of the present disclosure are provided for purpose of illustration only and do not limit the scope of the present disclosure, as exemplary embodiments disclosed herein may provide all or none of the above mentioned advantages and improvements and still fall within the scope of the present disclosure.

Specific dimensions, specific materials, and/or specific shapes disclosed herein are example in nature and do not limit the scope of the present disclosure. The disclosure herein of particular values and particular ranges of values for given parameters are not exclusive of other values and ranges of values that may be useful in one or more of the examples disclosed herein. Moreover, it is envisioned that any two particular values for a specific parameter stated herein may define the endpoints of a range of values that may be suitable for the given parameter (i.e., the disclosure of a first value and a second value for a given parameter can be interpreted as disclosing that any value between the first and second values could also be employed for the given parameter). For example, if Parameter X is exemplified herein to have value A and also exemplified to have value Z, it is envisioned that parameter X may have a range of values from about A to about Z. Similarly, it is envisioned that disclosure of two or more ranges of values for a parameter (whether such ranges are nested, overlapping or distinct) subsume all possible combination of ranges for the value that might be claimed using endpoints of the disclosed ranges. For example, if parameter X is exemplified herein to have values in the range of 1-10, or 2-9, or 3-8, it is also envisioned that Parameter X may have other ranges of values including 1-9, 1-8, 1-3, 1-2, 2-10, 2-8, 2-3, 3-10, and 3-9.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

The term “about” when applied to values indicates that the calculation or the measurement allows some slight imprecision in the value (with some approach to exactness in the value; approximately or reasonably close to the value; nearly). If, for some reason, the imprecision provided by “about” is not otherwise understood in the art with this ordinary meaning, then “about” as used herein indicates at least variations that may arise from ordinary methods of measuring or using such parameters. For example, the terms “generally”, “about”, and “substantially” may be used herein to mean within manufacturing tolerances. Or for example, the term “about” as used herein when modifying a quantity of an ingredient or reactant of the invention or employed refers to variation in the numerical quantity that can happen through typical measuring and handling procedures used, for example, when making concentrates or solutions in the real world through inadvertent error in these procedures; through differences in the manufacture, source, or purity of the ingredients employed to make the compositions or carry out the methods; and the like. The term “about” also encompasses amounts that differ due to different equilibrium conditions for a composition resulting from a particular initial mixture. Whether or not modified by the term “about”, the claims include equivalents to the quantities.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath”, “below”, “lower”, “above”, “upper” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The foregoing description of the embodiments has been provided for purposes of illustration and description. It is not intended to be exhaustive or to limit the disclosure. Individual elements, intended or stated uses, or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A thermal management and/or electromagnetic interference (EMI) mitigation material comprising one or more additives including at least one or more of:
one or more phosphors; and/or
one or more ultraviolet reactive additives; and/or
one or more taggants; and/or
one or more additives that are initially invisible to a naked human eye but increase in visibility to the naked human eye upon application of energy from an energy source corresponding to the one or more additives.

2. The thermal management and/or electromagnetic interference (EMI) mitigation material of claim 1, wherein the thermal management and/or electromagnetic interference (EMI) mitigation material includes an effective amount of the one or more phosphors such that, when infrared light is applied to at least a portion of the thermal management and/or electromagnetic interference (EMI) mitigation material including the one or more phosphors, the infrared light is converted into visible colored light, whereby the visible colored light is visible to a naked human eye and/or distinguishable from a surrounding.

3. The thermal management and/or electromagnetic interference (EMI) mitigation material of claim 1, wherein the thermal management and/or electromagnetic interference (EMI) mitigation material includes an effective amount of the one or more ultraviolet reactive additives to cause fluorescence when ultraviolet light is applied to at least a portion of the thermal management and/or electromagnetic interference (EMI) mitigation material including the one or more ultraviolet reactive additives, whereby the fluorescence is visible to a naked human eye and/or distinguishable from a surrounding.

4. The thermal management and/or electromagnetic interference (EMI) mitigation material of claim 1, wherein the thermal management and/or electromagnetic interference (EMI) mitigation material includes an effective amount of the one or more taggants that is detectable by a detector.

5. The thermal management and/or EMI mitigation material of claim 1, wherein the one or more additives are incorporated into a bulk material for the thermal management and/or EMI mitigation material without significantly altering thermal management and/or EMI mitigation properties of the thermal management and/or EMI mitigation material.

6. The thermal management and/or EMI mitigation material of claim 1, wherein the one or more additives enable detectability of the thermal management and/or electromagnetic interference (EMI) mitigation material without applying a surface coating or colorant to exterior surfaces of the thermal management and/or electromagnetic interference (EMI) mitigation material.

7. The thermal management and/or EMI mitigation material of claim 1, wherein:
the one or more additives enable detectability of the thermal management and/or electromagnetic interference (EMI) mitigation material from all exterior sides of the thermal management and/or electromagnetic interference (EMI) mitigation material; and/or
the thermal management and/or EMI mitigation material comprises a pad of thermal interface material including a top, a bottom, and four sides; and the one or more additives enable detectability of the top, the bottom, and the four sides of the pad of thermal interface material by using one or more of:
infrared light when the one or more additives comprise the one or more phosphors; and/or
ultraviolet light when the one or more additives comprise the one or more ultraviolet reactive additives; and/or
a taggant detector when the one or more additives comprise the one or more taggants.

8. The thermal management and/or EMI mitigation material of claim 1, wherein:
the one or more additives comprise the one or more ultraviolet reactive additives; and
the thermal management and/or EMI mitigation material comprises a thermally-conductive microwave absorber including the one or more ultraviolet reactive additives and having a hardness of about 58 Shore 00 and/or an effective thermal conductivity of about 1.31 Watts per meter per Kelvin.

9. The thermal management and/or EMI mitigation material of claim 1, wherein:
the one or more additives comprise the one or more ultraviolet reactive additives, and the one or more ultraviolet reactive additives comprise quinazolinone; and/or
the one or more additives comprise the one or more phosphors, and the one or more phosphors comprise up converting phosphors; and/or
the one or more additives comprise the one or more taggants, and the one or more taggants comprise molecular taggants.

10. The thermal management and/or EMI mitigation material of claim 1, wherein the thermal management and/or EMI mitigation material comprises at least one or more of:
a thermally-conductive microwave absorber including silicon carbide, carbonyl iron powder, and alumina; or
a thermally-conductive microwave absorber including silicon carbide, carbonyl iron powder, alumina, manganese zinc ferrite, and magnetic flakes; or
a surface wave absorber comprising a magnetically loaded silicone-based elastomeric sheet; or
a tuned frequency absorber comprising a sheet including one or more magnetic fillers in a polymeric binder; or
a thermal interface material comprising a thermally-conductive gap filler, a thermally-conductive silicone pad, and/or a thermally-conductive dielectric material; or
an EMI shielding material comprising an EMI absorber, an EMI suppression material, and/or electrically-conductive thermal insulator; or
a combined thermal interface and EMI shielding material comprising a thermally-conductive electrical conductor, a thermally-conductive EMI absorber, and/or a thermally conductive EMI suppression material.

11. An automated visual detection system for detecting the thermal management and/or EMI mitigation material of claim 1, wherein the automated visual detection system comprises at least one or more of:
an infrared light source such that the thermal management and/or EMI mitigation material is detectable by the automated visual detection system when the one or more additives comprise the one or more phosphors;
an ultraviolet light source such that the thermal management and/or EMI mitigation material is detectable by the automated visual detection system when the one or more additives comprise the one or more ultraviolet reactive additives; and
a taggant detector such that the thermal management and/or EMI mitigation material is detectable by the automated visual detection system when the one or more additives comprise the one or more taggants.

12. A method comprising adding one or more additives to a thermal management and/or EMI mitigation material, wherein the one or more additives include at least one or more of:
one or more phosphors; and/or
one or more ultraviolet reactive additives; and/or
one or more taggants; and/or
one or more additives that are initially invisible to a naked human eye but increase in visibility to the naked human eye upon application of energy from an energy source corresponding to the one or more additives.

13. The method of claim 12, wherein adding one or more additives to a thermal management and/or EMI mitigation material comprises adding an effective amount of the one or more phosphors such that when infrared light is applied to the thermal management and/or electromagnetic interference (EMI) mitigation material the infrared light is converted into visible colored light, whereby the visible colored light is visible to a naked human eye and/or distinguishable from a surrounding.

14. The method of claim 12, wherein adding one or more additives to a thermal management and/or EMI mitigation material comprises adding an effective amount of the one or more ultraviolet reactive additives to cause fluorescence when ultraviolet light is applied to at least a portion of the thermal management and/or electromagnetic interference (EMI) mitigation material including the one or more ultraviolet reactive additives, whereby the fluorescence is visible to a naked human eye and/or distinguishable from a surrounding.

15. The method of claim 12, wherein adding one or more additives to a thermal management and/or EMI mitigation material comprises adding an effective amount of the one or more taggants that is detectable by a taggant detector.

16. The method of claim 12, wherein adding one or more additives to a thermal management and/or EMI mitigation material comprises adding the one or more additives to a bulk material for the thermal management and/or EMI mitigation material.

17. The method of claim 12, wherein adding one or more additives to a thermal management and/or EMI mitigation material:
enables detectability of the thermal management and/or electromagnetic interference (EMI) mitigation material without applying a surface coating or colorant to exterior surfaces of the thermal management and/or electromagnetic interference (EMI) mitigation material; and/or
enables detectability of the thermal management and/or electromagnetic interference (EMI) mitigation material from all exterior sides of the thermal management and/or electromagnetic interference (EMI) mitigation material.

18. The method of claim 12, wherein:
the one or more additives comprise the one or more ultraviolet reactive additives, and the one or more ultraviolet reactive additives comprise quinazolinone; and/or
the one or more additives comprise the one or more phosphors, and the one or more phosphors comprise up converting phosphors; and/or
the one or more additives comprise the one or more taggants, and the one or more taggants comprise molecular taggants.

19. A method of detecting a thermal management and/or EMI mitigation material including one or more additives, the method comprising at least one or more of:
applying infrared light to at least a portion of the thermal management and/or EMI mitigation material including the one or more additives when the one or more additives comprise one or more phosphors; and/or
applying ultraviolet light to at least a portion of the thermal management and/or EMI mitigation material including the one or more additives when the one or more additives comprise one or more ultraviolet reactive additives; and/or
using a taggant detector along at least a portion of the thermal management and/or EMI mitigation material including the one or more additives when the one or more additives comprise one or more taggants; and/or
applying energy from an energy source corresponding to the one or more additives to at least a portion of the thermal management and/or EMI mitigation material including the one or more additives to thereby increase visibility of the one or more additives that are initially invisible to a naked human eye.

20. The method of claim 19, wherein:
the one or more additives comprise quinazolinone; and
the method includes applying ultraviolet light long wave 365 nanometers or short wave 254 nanometers to at least a portion of the thermal management and/or EMI mitigation material including the quinazolinone to cause fluorescence, whereby the fluorescence is visible to a human eye and/or distinguishable from a surrounding.

21. The method of claim 19, wherein:
the one or more additives comprise one or more phosphors; and
the method includes applying infrared light to at least a portion of the thermal management and/or EMI mitigation material including the one or more phosphors such that the infrared light is converted into visible colored light, whereby the visible colored light is visible to a naked human eye and/or distinguishable from a surrounding.

22. The method of claim 19, wherein:
the one or more additives comprise one or more ultraviolet reactive additives; and
the method includes applying ultraviolet light to at least a portion the thermal management and/or EMI mitigation material including the one or more ultraviolet reactive additives to cause fluorescence, whereby the fluorescence is visible to a human eye and/or distinguishable from a surrounding.

23. The method of claim 19, wherein:
the one or more additives comprise one or more taggants; and
the method includes using a taggant detector to detect the one or more taggants in the thermal management and/or electromagnetic interference (EMI) mitigation material.
